(19) United States
(12) Patent Application Publication
(10) Pub. No.: US 2015/0219698 A1
(43) Pub. Date: Aug. 6, 2015

(54) METHOD FOR SEPARATING THRESHOLD VOLTAGE SHIFTS CAUSED BY TWO EFFECTS IN SOI DEVICE

(71) Applicant: Peking University, Beijing (CN)

(72) Inventors: Xia An, Beijing (CN); Hui Feng, Beijing (CN); Liangxi Huang, Beijing (CN); Ru Huang, Beijing (CN)

(21) Appl. No.: 14/359,531

(22) PCT Filed: Jun. 5, 2013
(86) PCT No.: PCT/CN13/76748

§ 371 Date: May 20, 2014

(30) Foreign Application Priority Data
May 2, 2013 (CN) 201310157703.0

(51) Int. Cl. G01R 19/165; G01R 31/26

(52) U.S. Cl. CPC G01R 19/16528; G01R 31/2642

(57) ABSTRACT

The present invention discloses a method for separating SOI device threshold voltage shift under a DC HCl stress, which belongs to a semiconductor reliability test field. By means of this method, under the condition that stressing bias is applied simultaneously to a gate terminal and a drain terminal of the SOI PMOSFET, the influences of HCl effect and NBTI effect are separated on the threshold voltage shift under the DC HCl stress. Adopting the present invention helps to better understand degradation mechanisms from HCl effect under stress with V_{G}=V_{D}, so as to better build model for the device and more accurately predict the device lifetime.

The present application claims priority of Chinese Patent Application (No. 201310157703.0), filed on May 2, 2013, which is incorporated herein by reference in its entirety.

### TECHNICAL FIELD

The invention refers to a field of semiconductor reliability test, and generally refers to a method of testing the respective threshold voltage shifts caused by HCl effect and NBTI effect for a SOI PMOSFET.

### BACKGROUND OF THE INVENTION

Speaking of the development of integrated circuits, high performance and high reliability are two commanding heights of its development. On one hand, the integrated circuit technology develops toward a direction of greater integration degree and higher cost performance; on the other hand, driven by technology and market, the reliability is required to be continually improved, and VLSI reliability research is paid more attention day by day. The reliability of the integrated circuit is affected continually by the development of the device, and as integrated circuit technology is progressing, critical dimension of the device is continually decreased and the oxide layer is continually thinned, the internal field and the current density of the device continually increase and the sensitivity of the device property about defects is increased, so that a lot of reliability issues are more prominent, such as hot-carrier induced (HCl) effect, negative bias temperature instability (NBTI), gate oxide time dependent dielectric breakdown (TDDB), electromigration (EM) and so on.

SOI is the English abbreviation for silicon on insulator, refers to silicon on insulator layer. SOI CMOS device has the following advantages: low power consumption, strong anti-interference ability, high integration density, high speed, simple process, strong anti-radiation ability, and the complete elimination of the parasitic latch-up effect for the bulk silicon CMOS device, and so on. However, due to low thermal conductivity of a SOI buried oxide layer, there is self-heating effect in the SOI device. Therefore, the reliability research for the SOI device is more complex than that for bulk silicon.

After the device progresses into deep submicron phase, the SOI device has the worst stress bias condition of V_{G}=V_{D}. At this time, degradation of the device performance is the most serious. When the SOI PMOSFET is applied with a DC HCl stress with V_{G}=V_{D}=Vₛₜᵣₑₛₛ, due to the poorer thermal conductivity of its buried oxide layer and the raised channel temperature of the device. NBTI effect can be caused in the vertical electric field of the gate voltage, both HCl effect and NBTI effect jointly causing the threshold voltage shift of the device and resulting in degradation of the device performance. Therefore, separating of two reliability effects not only helps to understand degradation mechanisms of the device under the DC HCl stress, but also is conducive to more accurate prediction of the device lifetime.

### SUMMARY OF THE INVENTION

The present invention is to provide a method for separating the influences of HCl effect and NBTI effect on the threshold voltage shift under the condition that stress bias is applied simultaneously to a gate terminal and to a drain terminal of SOI PMOSFET.

The technical solution of this method is provided as follows.

A method for separating threshold voltage shifts caused by two reliability effects under a DC HCl stress in SOI device, where the specific solution flows are shown in FIG. 1.

1) Under the condition that the DC HCl stress is applied to a gate terminal and a drain terminal of the SOI PMOS device A with V_{G}=V_{D}=Vₛₜᵣₑₛₛ and V_{S}=0, a threshold voltage shift ΔV_{TH}_{_{—}}_{NBTI}^{pure} is measured, and a self-heating temperature ΔT_{SH} of the device is extracted by using a gate resistance method;

2) Using a SOI PMOS device B that is some as the SOI PMOS device A in process and dimension, under the condition that a NBTI stress bias is applied to the SOI PMOS device B with V_{D}=Vₛₜᵣₑₛₛ and V_{D}=V_{S}=0 and the self-heating temperature ΔT_{SH} of the device A is taken as a stress temperature T, a threshold voltage shift ΔV_{TH}_{_{—}}_{NBTI}^{pure} of the SOI PMOS device B is measured, which is equal to the threshold voltage shift caused by NBTI effect under the DC HCl stress in the SOI PMOS device A;

3) By subtracting the threshold voltage shift from NBTI, measured from the SOI PMOS device B, from the threshold voltage shift measured under the DC HCl stress from the SOI PMOS device A, the threshold voltage shift caused by HCl effect can be extracted, where the calculating Expression 4 is as follows:

ΔV_{TH}_{_{—}}_{HCl}^{pure}=ΔV_{TH}_{_{—}}_{HCl}^{TSET}−ΔV_{TH}_{_{—}}_{NBTI}^{pure} (4)

wherein, ΔV_{TH}_{_{—}}_{HCl}^{pure} is the extracted threshold voltage shift caused by HCl effect, ΔV_{TH}_{_{—}}_{HCl}^{TSET} is the threshold voltage shift measured under the DC HCl stress, and ΔV_{TH}_{_{—}}_{NBTI}^{pure} is the threshold voltage shift caused by NBTI effect.

In the present invention, under the condition that the stressing bias is applied simultaneously to the gate terminal and the drain terminal of the SOI PMOSFET, the influences of HCl effect and NBTI effect on the threshold voltage shift under the DC HCl stress are separated to extract the respective threshold voltage shift from HCl effect and NBTI effect respectively. Adopting the present invention helps to better understand the degradation mechanisms from HCl effect under the stress with V_{G}=V_{D}, so as to better build model for the device and more accurately predict the device lifetime.

### BRIEF DESCRIPTION OF THE DRAWINGS

FIG. 1 is a flow diagram of a technical solution according to the present invention;

FIG. 2 is a graph showing variations of gate resistance versus silicon wafer temperature under various voltage biases; and

FIG. 3 is a graph showing relationship between an extracted self-heating temperature and the voltage bias.

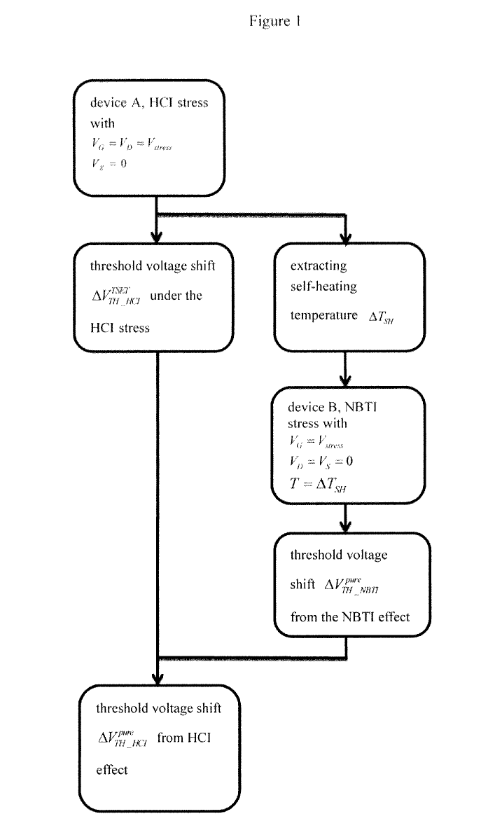

### DETAILED DESCRIPTION OF THE EMBODIMENTS

Hereinafter, the present invention ill be further described by the specific examples.

PDSOI PMOSFET having a gate electrode with a connection on each side thereof in 0.18 μm process is selected.

The invention adopts a gate resistance method to extract a SOI PMOSFET self-heating temperature, assuming that a gate electrode temperature is identical to a channel temperature. To prevent the inherent self-heating of the poly-silicon gate, gate voltages are selected as V_{G1}=V_{G}+ΔV and V_{G2}=V_{G}−ΔV, and a gate resistance is extracted by measuring small current flowing through the gate. Expression 1 shows a relationship between a thermal resistance and the self-heating temperature.

ΔT_{SH}=Rₜₕ×R_{disp}R_{disp}=I_{D}×V_{D} (1)

\textcircled{1} ΔT_{SH} is a device self-heating temperature, Rₜₕ is a device thermal resistance, R_{disp} is a device power consumption, I_{D} is a device drain terminal current, and V_{D} is a device operating voltage. Firstly, the resistance versus silicon wafer temperature variation relationships without self-heating effect under V_{G}=V_{D}=0 are tested, and then a variation coefficient α of the gate resistance variate versus the temperature is extracted, as shown in Expression 2. Gate resistance versus wafer temperature variation curves under various voltage biases are shown in the FIG. 2.

$$α = \frac{( Rg ( {T}_{high} ) - Rg ( {T}_{ref} ) ) / Rg ( {T}_{ref} )}{{T}_{high} - {T}_{ref}} ( {V}_{GS} = {V}_{DS} = 0 ) \qquad ( 2 )$$

α is the variation coefficient of the gate resistance variate versus the temperature under V_{GS}=V_{DS}=0, Rg(T_{high}) is a device gate resistance at a high silicon wafer temperature under V_{GS}=V_{DS}=0, Rg(T_{ref}) is a device gate resistance at a reference silicon wafer temperature, T_{high} is the high silicon wafer temperature, and T_{ref} is the reference silicon wafer temperature.

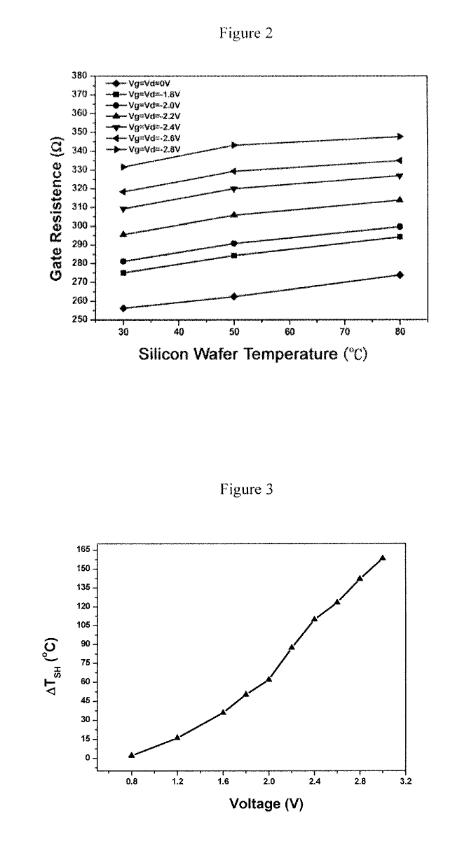

\textcircled{2} A device A is selected to be applied with a DC HCl stress at the room temperature with V_{G1}=−2.8V+20 mV, V_{G2}=−2.8V−20 mV, V_{D}=−2.8V and V_{S}=0V, and after a stress time of t=6000 s, the stress voltage is removed, then a threshold voltage shift ΔV_{TH}_{_{—}}_{HCl}^{TSET} is measured and the device gate resistance Rₜₕ=331.6Ω is measured. The self-heating temperature ΔT_{SH}=141° C. is obtained according to the Expression 3, in which the room temperature is adopted as the reference silicon wafer temperature, and the relationship of the extracted self-heating temperature under the room temperature versus the bias voltage is shown in FIG. 3.

$$Δ T ( SH ) = \frac{( Rth - Rg ( {T}_{ref} ) ) / Rg ( {T}_{ref} )}{α} \qquad ( 3 )$$

ΔT(SH) is a device self-heating temperature. Rth is a device gate resistance at the reference silicon wafer temperature under the HCl stress, Rg(T_{ref}) is the device gate resistance at the reference silicon wafer temperature under V_{GS}=V_{DS}=0, α is the variation coefficient of the gate resistance variate versus the temperature under V_{GS}=V_{DS}=0.

\textcircled{3} A device B is selected to be applied with a NBTI stress with V_{G}=−2.8V, V_{D}=V_{S}=0V and T=ΔT_{SH}=141° C., and after the stress time of t=6000 s, the stress voltage is removed, then a threshold voltage shift ΔV_{TH}_{_{—}}_{NBTI}^{pure}, which is approximately equal to a threshold voltage shift caused by the NBTI effect under the DC HCl stress in device A, is measured.

\textcircled{4} A threshold voltage shift ΔV_{TH}_{_{—}}_{HCl}^{pure} caused by HCl effect under the DC HCl stress is extracted using the following Expression.

ΔV_{TH}_{_{—}}_{HCl}^{pure}=ΔV_{TH}_{_{—}}_{HCl}^{TSET}−ΔV_{TH}_{_{—}}_{NBTI}^{pure}

Wherein, ΔV_{TH}_{_{—}}_{HCl}^{pure} is the extracted threshold voltage shift caused by HCl effect, ΔV_{TH}_{_{—}}_{HCl}^{TSET} is the measured threshold voltage shift under the DC HCl stress, and ΔV_{TH}_{_{—}}_{NBTI}^{pure} is the threshold voltage shift caused by NBTI effect.

The embodiments described as above are not constructed to limit the present invention, and various changes and modifications can be made by those skilled in the art without departing from the spirit and the scope of the present invention. Therefore, the protected scope of the present invention is defined by the claims.

What is claimed is:

1. A method for separating threshold voltage shift caused by two reliability effects under a DC HCl stress in the SOI device, comprising the steps of:
1) measuring a threshold voltage shift ΔV_{TH}_{_{—}}_{HCl}^{TSET} under the condition that the DC HCl stress is applied to a gate terminal and a drain terminal of a SOI PMOS device A with V_{G}=V_{D}=Vₛₜᵣₑₛₛ and V_{S}=0, and extracting a self-heating temperature ΔT_{SH} of the device;
2) measuring a threshold voltage shift ΔV_{TH}_{_{—}}_{NBTI}^{pure} of a SOI PMOS device B that is same as the SOI PMOS device A in process and dimension, which is equal to the threshold voltage shift caused by NBTI effect under the DC HCl stress in the SOI PMOS device, under the condition that a NBTI stress bias is applied to the SOI PMOS device B with V_{G}=Vₛₜᵣₑₛₛ, V_{D}=V_{S}=0, and the self-heating temperature ΔT_{SH} of the SOI PMOS device A being taken as a stress temperature T; and
3) calculating a threshold voltage shift ΔV_{TH}_{_{—}}_{HCl}^{pure} caused by HCl effect in the SOI PMOS device A from ΔV_{TH}_{_{—}}_{HCl}^{pure}=ΔV_{TH}_{_{—}}_{HCl}^{TSET}−ΔV_{TH}_{_{—}}_{NBTI}^{pure}.

2. The method according to claim 1, wherein, the step of extracting the self-heating temperature ΔT_{SH} of the SOI PMOS device is carried out by using a gate resistance method, comprising the steps of:
1) extracting the gate resistance by measuring a small current flowing through the gate;
2) testing the resistance versus silicon wafer temperature variation relationships without self-heating effect under V_{G}=V_{D}=0, and then extracting a variation coefficient α of the gate resistance variate versus the temperature;
3) measuring the gate resistance of the device under the condition that of the DC HCl stress is applied to the device, and obtaining the self-heating temperature ΔT_{SH} from Expression
$$Δ T ( SH ) = \frac{( Rth - Rg ( {T}_{ref} ) ) / Rg ( {T}_{ref} )}{α} .$$
